(19) United States
(12) Patent Application Publication
(10) Pub. No.: US 2026/0128725 A1
(43) Pub. Date: May 7, 2026

(54) PIEZOELECTRIC DEVICE

(71) Applicant: Murata Manufacturing Co., Ltd., Nagaokakyo-shi (JP)

(72) Inventor: Shintaro KUBO, Nagaokakyo-shi (JP)

(21) Appl. No.: 19/440,998

(22) Filed: Jan. 6, 2026

Related U.S. Application Data
(63) Continuation of application No. PCT/JP2024/019083, filed on May 23, 2024.

(30) Foreign Application Priority Data
Jul. 28, 2023 (JP) 2023-123666

(51) Int. Cl. H03H 9/15; H03H 9/13

(52) U.S. Cl. CPC H03H 9/15; H03H 9/13

(57) ABSTRACT

A piezoelectric device includes a piezoelectric layer including first and second principal surfaces opposed to each other, a support on a second principal surface side of the piezoelectric layer, a first functional electrode on at least one of the first and second principal surfaces, a substrate opposed to the first principal surface of the piezoelectric layer with a space therebetween and including a second functional electrode, and a shield between the piezoelectric layer and the substrate. The shield at least partially overlaps the first functional electrode in plan view in the first direction. A distance from a center of the shield to the piezoelectric layer is smaller than a distance from the center of the shield to the substrate.

### CROSS REFERENCE TO RELATED APPLICATIONS

This application claims the benefit of priority to Japanese Patent Application No. 2023-123666 filed on Jul. 28, 2023 and is a Continuation Application of PCT Application No. PCT/JP2024/019083 filed on May 23, 2024. The entire contents of each application are hereby incorporated herein by reference.

### BACKGROUND OF THE INVENTION

### 1. Field of the Invention

The present invention relates to piezoelectric devices.

### 2. Description of the Related Art

Japanese Unexamined Patent Application Publication No. 2005-252175 and Japanese Unexamined Patent Application Publication No. 2018-014717 disclose piezoelectric devices each of which includes two substrates that are opposed to each other with a distance therebetween, and is provided with a shield located between the two substrates so as to cover a functional electrode provided to one of the substrates.

The piezoelectric devices according to Japanese Unexamined Patent Application Publication No. 2005-252175 and Japanese Unexamined Patent Application Publication No. 2018-014717 are not capable of sufficiently dissipating operating heat from the functional electrode.

### SUMMARY OF THE INVENTION

Example embodiments of the present invention provide piezoelectric devices each having a high heat dissipation property of a functional electrode.

A piezoelectric device according to an example embodiment of the present invention includes a piezoelectric layer having a thickness in a first direction and including a first principal surface and a second principal surface on an opposite side from the first principal surface, a support on a second principal surface side of the piezoelectric layer, a first functional electrode on at least one of the first principal surface and the second principal surface of the piezoelectric layer, a substrate opposed to the first principal surface of the piezoelectric layer with a space in the first direction therebetween, including a second functional electrode, and having a thickness in the first direction, and a shield between the piezoelectric layer and the substrate. The shield is located at a position at least partially overlapping the first functional electrode in plan view in the first direction, and a distance from a center of the shield to the piezoelectric layer is smaller than a distance from the center of the shield to the substrate.

According to example embodiments of the present invention, piezoelectric devices each having a high heat dissipation property of a functional electrode are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic sectional view showing an example of a piezoelectric device according to a first example embodiment of the present invention.

FIG. 2 is a schematic plan view of the piezoelectric device according to the first example embodiment, which is viewed from a cross-section taken along line A-A in FIG. 1.

FIG. 3 is a schematic plan view of the piezoelectric device according to the first example embodiment, which is viewed from the cross-section taken along line A-A in FIG. 1.

FIG. 4 is a plan view showing a modification of the piezoelectric device according to the first example embodiment of the present invention.

FIG. 5 is a diagram for explaining an example of a method of manufacturing the piezoelectric device according to the first example embodiment of the present invention.

FIG. 6 is a diagram for explaining an example of a method of manufacturing the piezoelectric device according to the first example embodiment of the present invention.

FIG. 7 is a diagram for explaining an example of a method of manufacturing the piezoelectric device according to the first example embodiment of the present invention.

FIG. 8 is a schematic sectional view showing an example of a piezoelectric device according to a second example embodiment of the present invention.

FIG. 9 is a schematic sectional view showing an example of a piezoelectric device according to a third example embodiment of the present invention.

### DETAILED DESCRIPTION OF THE EXAMPLE EMBODIMENTS

Example embodiments of the present invention will be described in detail below with reference to the drawings. The present invention is not limited to the example embodiments. The respective example embodiments described in this disclosure are merely exemplary, and in modifications as well as in second and subsequent example embodiments that enable partial replacement or combination of configurations between different example embodiments, descriptions concerning matters common to the first example embodiment will be omitted and only different points therefrom will be explained. In particular, the same operations and advantageous effects attributed to the same or substantially the same configurations will not be described in each example embodiment one by one.

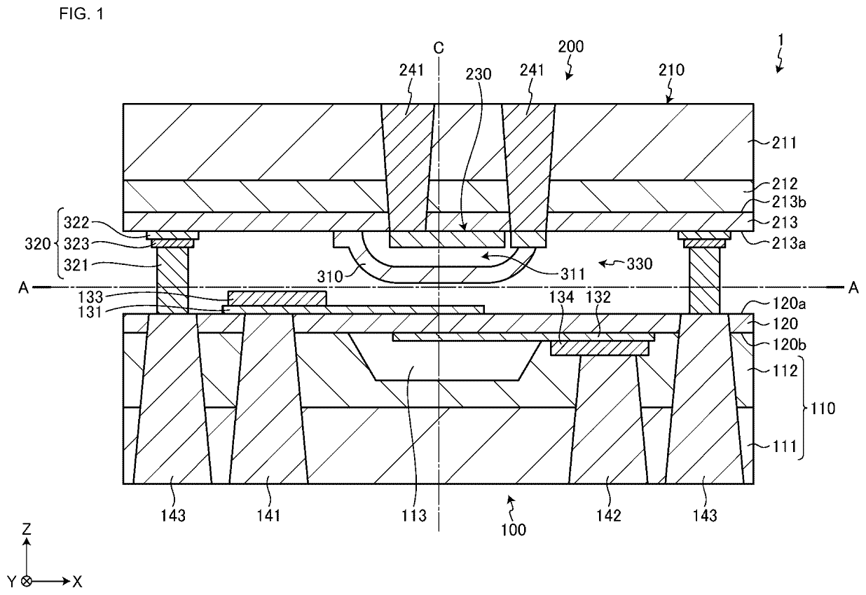

FIG. 1 is a schematic sectional view showing an example of a piezoelectric device according to a first example embodiment of the present invention. A piezoelectric device 1 according to the first example embodiment includes a first element 100, a second element 200, a shield 310, and a seal 320. In the following description, a thickness direction of the first element 100 and the second element 200 will be explained as Z direction, a direction orthogonal to the Z direction will be explained as X direction, and a direction orthogonal to the Z direction and the X direction will be explained as Y direction. The first element 100 and the second element 200 are opposed to each other with a space in the Z direction therebetween.

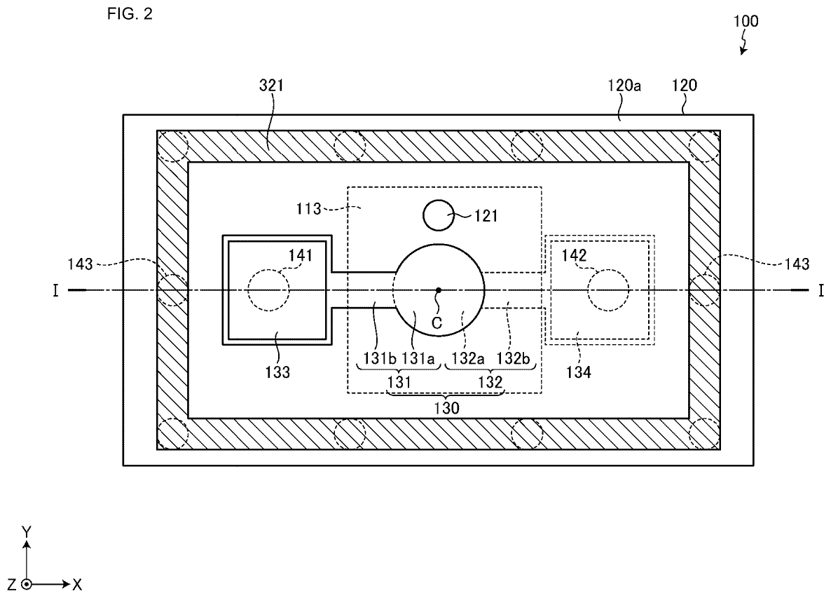

FIG. 2 is a schematic plan view of the piezoelectric device according to the first example embodiment, which is viewed from a cross-section taken along line A-A in FIG. 1. To be more precise, FIG. 2 is the plan view that represents a plan view of the first element 100 from the Z direction. The first element 100 is a piezoelectric element that utilizes, for example, a bulk wave, that is, a BAW (bulk acoustic wave) element. As shown in FIG. 1 and FIG. 2, the first element 100 includes a support 110, a piezoelectric layer 120, a first functional electrode 130, wiring electrodes 133 and 134, and through electrodes 141 to 143.

The piezoelectric layer 120 is a plate-shaped layer including a first principal surface 120a and a second principal surface 120b on an opposite side from the first principal surface 120a. Here, the first principal surface 120a is opposed to the second element 200 in the Z direction. In the first example embodiment, the piezoelectric layer 120 is a substrate made of, for example, a single crystal of lithium niobate (LiNbO₃), lithium tantalate (LiTaO₃), crystal, or the like which can excite the bulk wave.

As shown in FIG. 2, the piezoelectric layer 120 is provided with a through hole 121. The through hole 121 is a hole that passes through the piezoelectric layer 120 in the Z direction. The through hole 121 is provided at a portion overlapping a void portion 113 to be described later in plan view in the Z direction. Note that the configuration of the through hole 121 is not limited to the example of FIG. 2 as long as the through hole 121 is provided at the position overlapping the void portion 113. For example, the through hole 121 may be configured to pass through an upper electrode 131 and a lower electrode 132 to be described later.

The first functional electrode 130 includes the upper electrode 131 and the lower electrode 132. As shown in FIG. 1, the upper electrode 131 is provided at the first principal surface 120a of the piezoelectric layer 120, and the lower electrode 132 is provided at the second principal surface 120b of the piezoelectric layer 120. The upper electrode 131 includes a circular main electrode portion 131a and an extending portion 131b that extends in the X direction from the main electrode portion 131a. Similarly, the lower electrode 132 includes a circular main electrode portion 132a and an extending portion 132b that extends in the X direction from the main electrode portion 132a. The upper electrode 131 and the lower electrode 132 are made of a metal or an alloy of, for example, aluminum (Al), platinum (Pt), copper (Cu), tungsten (W), molybdenum (Mo), or the like. Here, the upper electrode 131 and the lower electrode 132 may include an adhesion layer made of, for example, titanium (Ti), a nickel-chromium alloy (NiCr), or the like.

In the first example embodiment, the circular main electrode portion 131a of the upper electrode 131 overlaps the circular main electrode portion 132a of the lower electrode 132 in plan view in the Z direction. In other words, the piezoelectric layer 120 is interposed between the circular main electrode portion 131a of the upper electrode 131 and the circular main electrode portion 132a of the lower electrode 132. Thus, the bulk wave is propagated between the circular main electrode portion 131a of the upper electrode 131 and the circular main electrode portion 132a of the lower electrode 132. The shapes of the upper electrode 131 and the lower electrode 132 are mere examples and are not limited to these shapes. In the following description, a region where the upper electrode 131 overlaps the lower electrode 132 in plan view in the Z direction may be explained as an excitation region of the first functional electrode 130 in some cases.

As shown in FIG. 2, the wiring electrode 133 of the upper electrode is provided in the Z direction of the extending portion 131b. The wiring electrode 133 of the upper electrode is provided on the first principal surface 120a side of the piezoelectric layer 120. The wiring electrode 133 of the upper electrode is made of, for example, a metal or an alloy of aluminum (Al), platinum (Pt), copper (Cu), tungsten (W), molybdenum (Mo), or the like. Here, the wiring electrode 133 of the upper electrode may include an adhesion layer made of, for example, titanium (Ti), a nickel-chromium alloy (NiCr), or the like.

As shown in FIG. 2, the wiring electrode 134 of the lower electrode is provided in the Z direction of the extending portion 132b. The wiring electrode 134 of the lower electrode is provided on the second principal surface 120b side of the piezoelectric layer 120. The wiring electrode 133 of the upper electrode and the wiring electrode 134 of the lower electrode are made of, for example, a metal or an alloy of Al, Pt, Cu, W, Mo, or the like. Here, the wiring electrode 133 of the upper electrode and the wiring electrode 134 of the lower electrode may include an adhesion layer made of, for example, Ti, NiCr, or the like.

The support 110 is opposed to the second principal surface 120b of the piezoelectric layer 120. In the first example embodiment, the support 110 includes a support substrate 111 and an intermediate layer 112. The support substrate 111 is a substrate made of, for example, silicon (Si), crystal, or the like. The intermediate layer 112 is a layer made of, for example, silicon oxide or the like. The intermediate layer 112 is provided on the piezoelectric layer 120 side relative to the support substrate 111. Here, the support 110 need not include the intermediate layer 112, and the support substrate 111 may be in contact with the second principal surface 120b side of the piezoelectric layer 120.

The support 110 is provided with the void portion 113. In the example embodiment shown in FIG. 2, the void portion 113 is a space inside a recessed portion provided on the piezoelectric layer 120 side of the intermediate layer 112. The void portion 113 overlaps the excitation region of the first functional electrode 130 in plan view in the Z direction. In this way, it is possible to reduce or prevent leakage of energy of the bulk wave. The void portion 113 is not limited to the example shown in FIG. 1, but may be configured to extend through the intermediate layer 112, and may also be provided on the piezoelectric layer 120 side of the support substrate 111. Meanwhile, in the example shown in FIG. 2, a shape of an outer wall of the void portion 113 is rectangular or substantially rectangular. However, this is merely exemplary and the shape is not limited thereto. The shape may be other shapes such as a circular shape, for example.

The through electrodes 141 and 142 are extended electrodes for the first element 100 and are made of a conductor such as, for example, copper (Cu). The through electrode 141 is electrically connected to the upper electrode 131 through the wiring electrode 133. Similarly, the through electrode 142 is electrically connected to the lower electrode 132 through the wiring electrode 134. The through electrode 141 extends through the support 110 and the piezoelectric layer 120 in the Z direction. The through electrode 142 extends through the support 110 in the Z direction. Thus, the first element 100 can be connected to an external element by providing bumps to end portions on the sides of the through electrodes 141 and 142 not connected to the upper electrode 131 or the lower electrode 132. Here, in a case where multiple resonators are connected in series or in parallel, one through electrode may be connected to the functional electrode for each resonator or the through electrode need not be connected thereto.

The through electrode 143 is an extended electrode for the seal 320 to be described later, and is made of a conductor such as, for example, copper (Cu). The through electrode 143 is electrically connected to the seal 320. The through electrode 143 passes through the support 110 and the piezoelectric layer 120 in the Z direction. Thus, it is possible to establish grounding by providing a bump at an end portion of the through electrode 143 on the side not connected to the seal 320. Here, although multiple pieces are provided with a space therebetween at positions overlapping a second portion 322 of the seal 320 in the example of FIG. 2, this is merely exemplary and the present invention is not limited to this configuration. Meanwhile, the through electrode 143 need not be provided in a case where the seal 320 is defined by an insulator.

Here, the through electrodes provided to the first element 100 are not limited to the above-described through electrodes 141 to 143. For example, a through electrode to be electrically connected to a second functional electrode 230 that will be described later may further be provided.

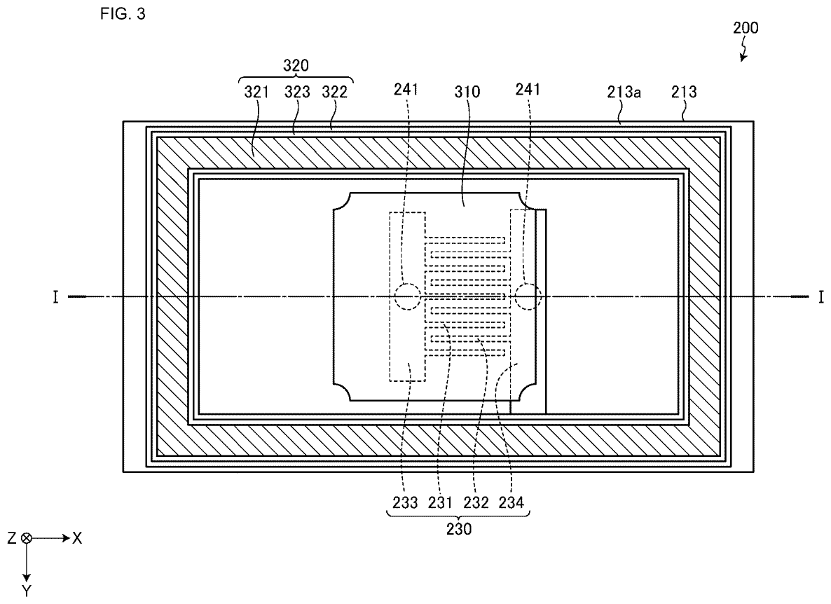

FIG. 3 is a schematic plan view of the piezoelectric device according to the first example embodiment, which is viewed from the cross-section taken along line A-A in FIG. 1. To be more precise, FIG. 3 is the plan view that represents a plan view of the second element 200 from the Z direction. The second element 200 is, for example, a SAW (surface acoustic wave) element that includes an IDT (interdigitated transducer) electrode. As shown in FIG. 1 and FIG. 3, the second element 200 includes a substrate 210, the second functional electrode 230, and through electrodes 241.

The substrate 210 is spaced away from and opposed to a piezoelectric layer 213 in the Z direction. The substrate 210 according to the first example embodiment includes a support substrate 211, an intermediate layer 212, and the piezoelectric layer 213.

The support substrate 211 is a substrate made of, for example, silicon (Si), crystal, or the like.

The intermediate layer 212 is a layer made of, for example, silicon oxide or the like. The intermediate layer 212 is provided on the piezoelectric layer 213 side relative to the support substrate 211. The intermediate layer 212 is not an essential structure.

The piezoelectric layer 213 is a plate-shaped layer made of, for example, a single crystal of lithium niobate (LiNbO₃), lithium tantalate (LiTaO₃), crystal, or the like which can excite the bulk wave. The piezoelectric layer 213 is provided on the intermediate layer 212 on an opposite side from the support substrate 211. The piezoelectric layer 213 includes a first principal surface 213a and a second principal surface 213b on an opposite side from the first principal surface 213a. The first principal surface 213a is opposed to the first element 100 in the Z direction.

The second functional electrode 230 includes comb-shaped electrodes. The second functional electrode 230 is made of, for example, a metal or an alloy of aluminum (Al), platinum (Pt), copper (Cu), tungsten (W), molybdenum (Mo), or the like. Here, the second functional electrode 230 may include an adhesion layer made of, for example, titanium (Ti), a nickel-chromium alloy (NiCr), or the like.

The second functional electrode 230 includes a pair of comb-shaped electrodes connected to different electric potentials. As shown in FIG. 3, the second functional electrode 230 includes first electrode fingers 231, second electrode fingers 232, a first busbar 233, and a second busbar 234. Each first electrode finger 231 extends in the X direction and one end portion in the X direction thereof is connected to the first busbar 233. The first busbar 233 extends in the Y direction. Each second electrode finger 232 extends in the X direction and one end portion in the X direction thereof is connected to the second busbar 234. The second busbar 234 extends in the Y direction. In the first example embodiment, the first electrode fingers 231 and the first busbar 233 are connected to a hot potential through one of the through electrodes 241, while the second electrode fingers 232 and the second busbar 234 are connected to a ground potential through the other through electrode 241. Thus, a resonator is defined by the second functional electrode 230 and the substrate 210.

Each of the first electrode fingers 231 and the second electrode fingers 232 has a rectangular or substantially rectangular shape and includes a longitudinal direction. In a direction orthogonal or substantially orthogonal to this longitudinal direction, a first electrode finger 231 is opposed to a second electrode finger 232 located adjacent to the first electrode finger 231. The longitudinal direction of the first electrode fingers 231 and the second electrode fingers 232 as well as the direction orthogonal or substantially orthogonal to the longitudinal direction of the first electrode fingers 231 and the second electrode fingers 232 are directions intersecting with a thickness direction of the piezoelectric layer 213. Accordingly, the first electrode finger 231 and the second electrode finger 232 located adjacent to the first electrode finger 231 are opposed to each other in the direction intersecting with the thickness direction of the piezoelectric layer 213.

In the following description, a region where the first electrode finger 231 and the second electrode finger 232 located adjacent to each other overlap when viewed in a direction of opposition will be explained as an excitation region of the second functional electrode 230. Here, the state of the first electrode finger 231 and the second electrode finger 232 being located adjacent to each other does not represent a case where the first electrode finger 231 and the second electrode finger 232 are in direct contact with each other but represents a case where the first electrode finger 231 and the second electrode finger 232 are disposed with a space therebetween. Meanwhile, in the case where the first electrode finger 231 and the second electrode finger 232 are located adjacent to each other, electrodes inclusive of the remaining first electrode fingers 231 and the remaining second electrode fingers 232 to be connected to the hot electrode or the ground electrode are not disposed between the relevant first electrode finger 231 and the relevant second electrode finger 232. The number of pairs does not have to be an integral number but may be 1.5 pairs, 2.5 pairs, or the like, for example.

In the example of FIG. 3, an end portion in the Y direction of the second busbar 234 is electrically connected to the second portion 322 of the seal 320. Thus, the second busbar 234 is connected to a reference potential. Here, the second busbar 234 need not be connected to the second portion 322. Meanwhile, the first busbar 233 may be connected to the second portion 322.

The shield 310 is a plate-shaped member that blocks electromagnetic waves. The shield 310 is provided between the piezoelectric layer 120 and the piezoelectric layer 213. In the first example embodiment, the shield 310 is provided between the excitation region of the first functional electrode 130 and the excitation region of the second functional electrode 230 with distances in plan view in a first direction. This makes it possible to reduce or prevent an impact of an electromagnetic wave generated by an operation of one of the functional electrodes of the first functional electrode 130 and the second functional electrode 230 on an operation of the other functional electrode.

The through electrodes 241 are extended electrodes of the second element 200 and are made of a conductor such as, for example, copper (Cu). The through electrodes 241 are electrically connected to the second functional electrode 230. In the example of FIG. 1, the through electrodes 241 are each connected to corresponding one of the first busbar 233 and the second busbar 234. The through electrodes 241 extend through the support substrate 211, the intermediate layer 212, and the piezoelectric layer 213 in the Z direction. Thus, the second element 200 can be connected to an external element by providing bumps at end portions on the side of the through electrodes 241 not connected to the second functional electrode 230. Here, in the case where multiple resonators are connected in series or in parallel, one through electrode may be connected to the functional electrode for each resonator or the through electrode need not be connected thereto.

A distance from a center C of the shield 310 to the piezoelectric layer 120 is smaller than a distance from the center C of the shield 310 to the substrate 210 of the second element 200. Here, the center C of the shield 310 means a position overlapping a geometric center of the excitation region of the first functional electrode 130 in plan view in the Z direction. In the example of FIG. 2, the geometric center of the excitation region of the first functional electrode 130 means the center of the circle of the main electrode portions 131a and 132a. Meanwhile, in a case where the shape of the main electrode portion is rectangular or substantially rectangular in plan view in the Z direction, the geometric center of the excitation region of the first functional electrode means an intersecting point of diagonal lines of the rectangle of the main electrode portion. In the meantime, the distance from the center C of the shield 310 to the piezoelectric layer 120 means a distance in the Z direction from a surface on the piezoelectric layer 120 side of the center C of the shield 310 to the first principal surface 120a of the piezoelectric layer 120. On the other hand, the distance from the center C of the shield 310 to the substrate 210 of the second element 200 means a distance in the Z direction from a surface on the second element 200 side of the center C of the shield 310 to the principal surface (the first principal surface 213a) on the first element side of the substrate 210 of the second element 200. Thus, operating heat of the first functional electrode 130 is more likely to be conducted to the shield 310, so that a heat dissipation property of the first functional electrode 130 can be improved even in the case where the void portion 113 is provided. Here, the distance from the center C of the shield 310 to the piezoelectric layer 120 and the distance from the center C of the shield 310 to the substrate 210 of the second element 200 can be measured by observing a cross-section of the piezoelectric device 1 taken along the Z direction with an SEM (scanning electron microscope), for example.

The shield 310 is made of a conductor. Thus, the shield 310 can block the electromagnetic waves. The shield 310 is preferably made of a metal having high thermal conductivity such as aluminum (Al), copper (Cu), gold (Au), or silver (Ag), for example. Thus, the heat dissipation property of the first functional electrode 130 can be improved.

In the first example embodiment, the shield 310 is electrically connected to the ground. In the example of FIG. 1, one end in the X direction of the shield 310 is provided on the first principal surface 213a of the piezoelectric layer 213, and another end in the X direction of the shield 310 is provided on the Z direction side of the second busbar 234 of the second functional electrode 230 connected to the ground. However, this is merely exemplary and the present invention is not limited to this configuration. For example, the one end in the X direction of the shield 310 may be provided at the first principal surface 120a of the piezoelectric layer 120 of the first element 100, and the other end in the X direction of the shield 310 need not be provided at the second functional electrode 230.

In the first example embodiment, the shield 310 has an arch shape in plan view from the X direction, which is curved to project toward the first principal surface 120a side of the piezoelectric layer 120. A strength of the shield 310 can be improved by providing this shape. In the example of FIG. 1, the shield 310 has a shape such that the neighborhood of the center C is flat. In other words, the shield 310 is provided to cover the second functional electrode 230. Meanwhile, there is a void 311 between the shield 310 and the first principal surface 213a of the piezoelectric layer 213.

In the first example embodiment, the shield 310 is flat in the Y direction. That is to say, the void 311 between the shield 310 and the first principal surface 213a of the piezoelectric layer 213 includes an opening at an end portion in the Y direction, and communicates with a void 330 between the piezoelectric layer 120 and the substrate 210 of the second element 200.

In the example of FIG. 3, the shield 310 is configured into a rectangle that does not include apices in plan view in the Z direction. However, this is merely exemplary and the present invention is not limited to this shape.

The seal 320 seals the void between the piezoelectric layer 120 and the substrate 210. In the first example embodiment, the seal 320 has a frame shape that surrounds the first functional electrode 130 and the second functional electrode 230 in plan view in the Z direction. Thus, the void 330 surrounded by the piezoelectric layer 120, the substrate 210, and the seal 320 is a closed void.

In the first example embodiment, the void 330 is airtight. Moreover, a pressure inside the void 330 is higher than an atmospheric pressure. Here, the atmospheric pressure means the atmospheric pressure in a standard state, which is about 101325 Pa. In this way, heat dissipation attributed to convection is provided so that a heat dissipation effect inside the void 330 can be improved. The void 330 preferably has an inert gas atmosphere including a light element such as helium (He), for example. Thus, it is possible to further improve the heat dissipation effect of the first functional electrode 130 while reducing or preventing deterioration in excitation characteristics of the first functional electrode 130.

In the first example embodiment, the seal 320 includes a first portion 321, a second portion 322, and a bonding portion 323. The first portion 321 is provided at the first principal surface 120a of the piezoelectric layer 120. The second portion 322 is provided at a position overlapping the first portion 321 in plan view in the Z direction, and is provided at the first principal surface 213a of the piezoelectric layer 213. The bonding portion 323 is provided between the first portion 321 and the second portion 322 in the Z direction, and bonds the first portion 321 to the second portion 322. For example, the seal 320 is made of a metal, an insulator, or the like. To be more precise, the first portion 321 and the second portion 322 are made of aluminum (Al), for example, and the bonding portion 323 is made of gold (Au), for example.

The piezoelectric device according to the first example embodiment is not limited to the above-described device.

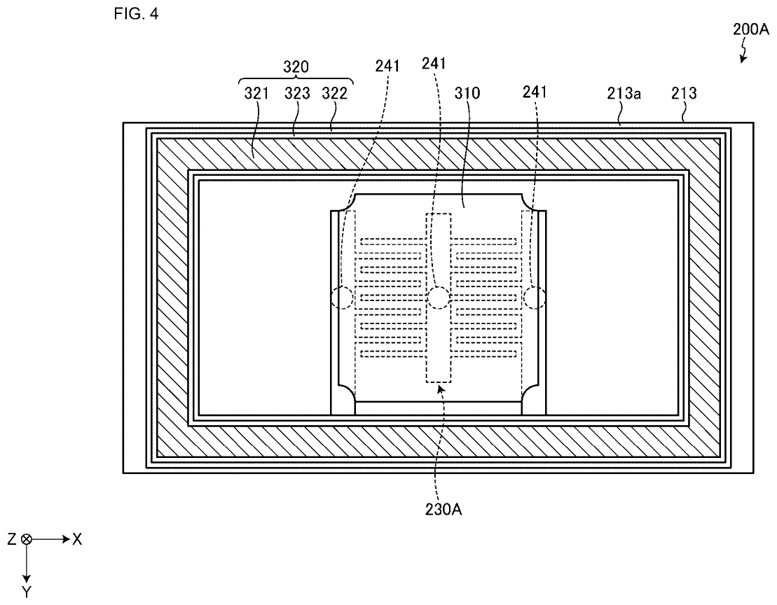

FIG. 4 is a plan view showing a modification of the piezoelectric device according to the first example embodiment of the present invention. To be more precise, FIG. 4 is a plan view showing a second element 200A according to the modification of the piezoelectric device of the first example embodiment. As shown in FIG. 4, the shield 310 may overlap multiple resonators provided to the second element. In the example of FIG. 4, two resonators located adjacent to each other in the X direction include a second functional electrode 230A and the substrate 210. However, this is merely exemplary. For example, the shield 310 may overlap three or more resonators, or overlap two or more resonators located adjacent in the Y direction. Meanwhile, in the shield 310 in the example of FIG. 4, the busbars on outer sides in the X direction of the two resonators are electrically connected to the ground by causing the Y direction thereof to be connected to the second portion 322 of the seal 320. However, this is merely exemplary. In the meantime, in the example of FIG. 4, end portions in the X direction of the shield 310 are in contact with the busbars in the Z direction on the outer sides in the X direction of the two resonators. However, this is merely exemplary and the shield 310 only needs to be electrically connected to the ground potential.

Meanwhile, the above description has explained the example in which the first element is a BAW element and the second element is a SAW element. However, the combination of the first element and the second element is not limited thereto. The first element may be another device that utilizes a ferroelectric substance, and the second element may be an element that does not use a piezoelectric substance. For example, the first element may be a BAW element, a SAW element, or a MEMS (micro electro mechanical systems) high frequency element and the second element may be an LSI (large scale integration). In this case, the shield 310 makes it possible to prevent an impact of a parasitic capacitance attributed to the first element that utilizes the ferroelectric substance from reaching the second element that does not utilize the ferroelectric substance.

Meanwhile, the shield may overlap multiple resonators provided in the first element. In this case, the center of the shield means the geometric centers of excitation regions of the respective resonators in plan view in the Z direction. That is to say, multiple centers may exist in the shield. In this case, distances from the multiple centers of the shield to the piezoelectric layer are smaller than distances from the respective centers of the shield to the substrate 210 of the second element. Here, in the case where the resonator is the BAW or MEMS high frequency element, the excitation region of the resonator means a region where the functional electrodes overlap each other in plan view in the Z direction, or in the case where the resonator is the SAW that includes the IDT electrode, the excitation region means a region where comb-shaped electrode portions of the IDT electrode overlap when viewed in an opposing direction thereof.

As described above, the piezoelectric device according to the first example embodiment includes the piezoelectric layer 120 having a thickness in the first direction and including the first principal surface 120a and the second principal surface 120b on the opposite side from the first principal surface 120a, the support 110 provided on the second principal surface 120b side of the piezoelectric layer 120, the first functional electrode 130 provided on any of the first principal surface 120a and the second principal surface 120b of the piezoelectric layer 120, the substrate 210 being opposed to the first principal surface 120a of the piezoelectric layer 120 with a distance in the first direction, including the second functional electrode 230, and having a thickness in the first direction, and the shield 310 provided between the piezoelectric layer 120 and the substrate 210. The shield 310 is provided at the position at least partially overlapping the first functional electrode 130 in plan view in the first direction. The distance from the center C of the shield 310 to the piezoelectric layer 120 is smaller than the distance from the center C of the shield 310 to the substrate 210. Thus, the operating heat of the first functional electrode 130 is more likely to be conducted to the shield 310, so that the heat dissipation property of the first functional electrode 130 can be improved.

Preferably, the support 110 includes the void portion 113 at the position at least partially overlapping the first functional electrode 130 in plan view in the first direction. In this case as well, the excitation characteristics of the first functional electrode can be improved while reducing or preventing deterioration in heat dissipation property of the first functional electrode 130.

Preferably, the shield 310 is provided at the position at least partially overlapping the second functional electrode 230 in plan view in the first direction. Accordingly, it is possible to reduce or prevent the impact of the electromagnetic wave generated by the operation of the first functional electrode 130 on the operation of the second functional electrode 230.

Preferably, the seal 320 is provided between the piezoelectric layer 120 and the substrate 210. The first functional electrode 130 is provided in a region surrounded by the seal 320 in plan view in the first direction. The void 330 surrounded by the piezoelectric layer 120, the substrate 210, and the seal 320 is airtight. The pressure inside the void 330 is higher than the atmospheric pressure. Thus, the heat dissipation attributed to the convection is provided so that the heat dissipation property can be further improved.

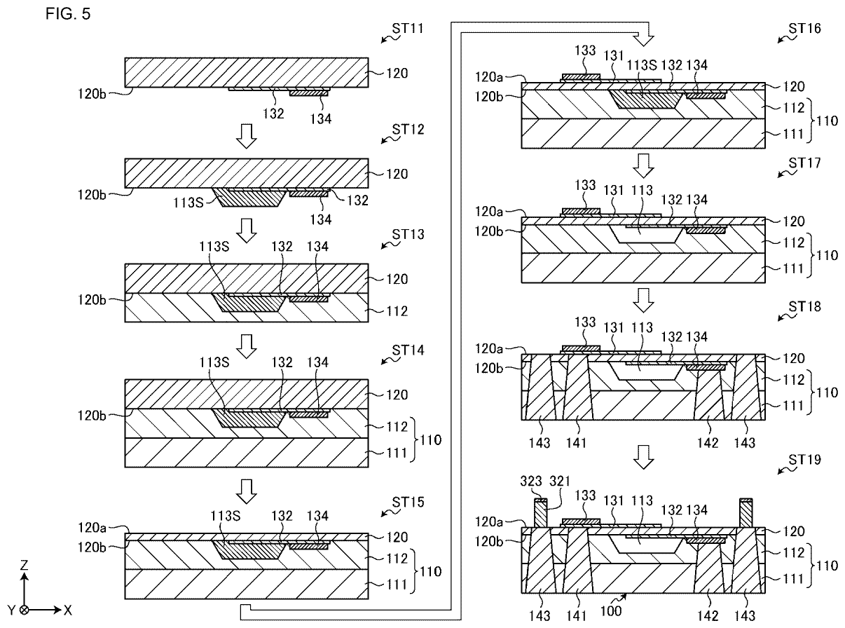

Next, an example of a method of manufacturing a piezoelectric device according to the present example embodiment will be described. FIG. 5 to FIG. 7 are diagrams for explaining an example of a method of manufacturing the piezoelectric device according to the first example embodiment. The method of manufacturing the piezoelectric device according to the present example embodiment includes a process (steps ST11 to ST19) of forming the first element 100, a process (steps ST21 to ST28) of forming the second element 200, and a process of bonding the first element 100 to the second element 200 (step ST30).

FIG. 5 is a diagram for explaining the process of manufacturing the first element 100. The process (steps ST11 to ST19) of forming the first element 100 will be described below with reference to FIG. 5.

As shown in FIG. 5, the lower electrode 132 and the wiring electrode 134 are formed at the second principal surface 120b of the piezoelectric layer 120 (step ST11). The lower electrode 132 and the wiring electrode 134 are formed by a deposition lift-off method, for example. That is to say, in step ST11, a resist is formed into a pattern on the second principal surface 120b of the piezoelectric layer 120 by photolithography, and a metal is vapor-deposited thereon. Thereafter, the resist is removed and a metal film located at a position where the resist is not removed is formed as the lower electrode 132 and the wiring electrode 134.

Next, a sacrificial layer 113S is formed at the second principal surface 120b of the piezoelectric layer 120 (step ST12). The sacrificial layer 113S is provided at a region to form the void portion 113 of the support 110 (the intermediate layer 112). In other words, the sacrificial layer 113S is provided to cover the main electrode portion 132a of the lower electrode 132. The sacrificial layer 113S is formed into a film by, for example, sputtering using a material such as zinc oxide (ZnO).

Next, the intermediate layer 112 is provided at the second principal surface 120b of the piezoelectric layer 120 to cover the lower electrode 132 and the sacrificial layer 113S (step ST13). The intermediate layer 112 is formed into a film by, for example, a sputtering method while using a material such as silicon oxide. An adhesion layer of, for example, Ti, NiCr, or the like may be provided between layers of the lower electrode 132 and the intermediate layer 112. Meanwhile, a surface of the intermediate layer 112 on the opposite side from the piezoelectric layer 120 may be subjected to a planarization process by, for example, CMP (chemical-mechanical polishing) as appropriate.

Next, the support substrate 111 is bonded to the second principal surface 120b of the piezoelectric layer 120. Thus, the support substrate 111 and the piezoelectric layer 120 are attached to each other (step ST14). The support substrate 111 is bonded to the piezoelectric layer 120 by, for example, direct bonding, plasma-activated bonding, atomic diffusion bonding, or the like.

Next, the piezoelectric layer 120 is formed into a thin plate by subjecting the piezoelectric layer 120 to grinding and polishing (step ST15). The piezoelectric layer 120 is subjected to polishing by mechanical polishing or CMP, for example. In this manner, the piezoelectric layer 120 is formed with a thickness equal to or below about 1 μm. The method of forming the piezoelectric layer 120 into the thin film in step ST15 is not limited to polishing. For example, a damage layer may be formed inside the piezoelectric layer 120 by ion implantation, and the piezoelectric layer 120 may be formed into a thin film by peeling a layer located on a first principal surface of the formed damage layer.

Next, the upper electrode 131 and the wiring electrode 133 are formed at the first principal surface 120a of the piezoelectric layer 120 (step ST16). The upper electrode 131 and the wiring electrode 133 are formed by a deposition lift-off method as with the above-described lower electrode 132, for example. That is to say, for example, in step ST16, a resist is formed into a pattern on the first principal surface 120a of the piezoelectric layer 120 by photolithography, and a metal is vapor-deposited thereon. Thereafter, the resist is removed and a metal film located at a position where the resist is not removed is formed as the upper electrode 131 and the wiring electrode 133.

Next, the sacrificial layer 113S is removed and the void portion 113 is formed at the intermediate layer 112 (step ST17). The sacrificial layer 113S is removed by wet etching, for example. In this case, an etchant for dissolving the sacrificial layer 113S is poured in from the through hole 121 formed in the piezoelectric layer 120 by a method such as RIE, for example.

Next, the through electrodes 141 to 143 are formed to extend through the support 110 (step ST18). In the first example embodiment, multiple pores are formed from the principal surface of the support 110 on the opposite side from the piezoelectric layer 120 to extend through the upper electrode 131, the wiring electrode 134, and the first principal surface 120a in the Z direction, and each of the through electrodes 141 to 143 is formed by filling the formed pores by plating. In the first example embodiment, the pores for providing the through electrodes 141 to 143 are formed by DRIE (deep RIE), for example.

Then, the first portion 321 and the bonding portion 323 of the seal 320 are formed at the first principal surface 120a of the piezoelectric layer 120 (step ST19). The first portion 321 and the bonding portion 323 of the seal 320 are formed by a deposition lift-off method, for example. That is to say, for example, in step ST19, a resist is formed into a pattern on the first principal surface 120a of the piezoelectric layer 120 by photolithography, and a metal is vapor-deposited thereon. Thereafter, the resist is removed and a metal film located at a position where the resist is not removed is formed as the first portion 321 and the bonding portion 323.

The first element 100 of the present example embodiment can be manufactured by the above-described process. The process shown in FIG. 5 is merely schematically illustrated and can be modified as appropriate.

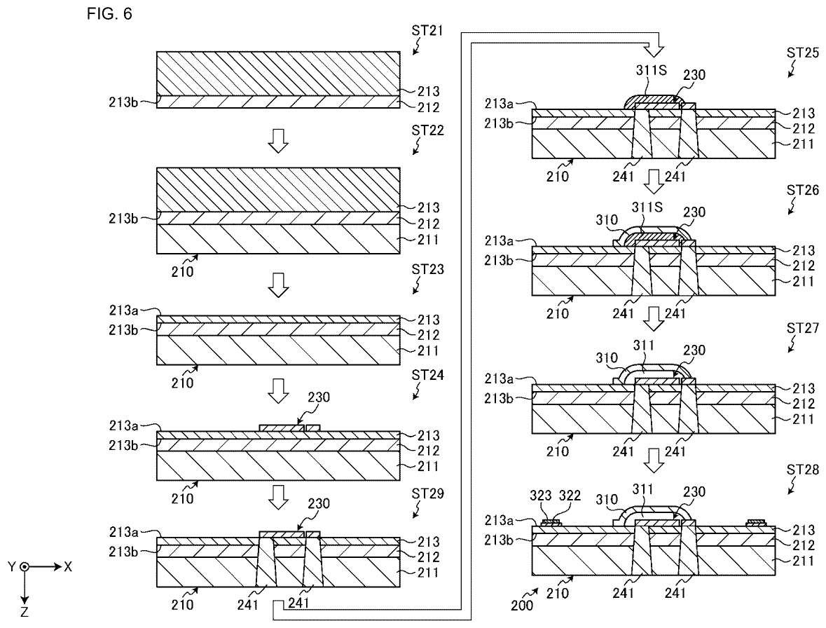

FIG. 6 is a diagram for explaining the process of forming the second element 200. The process (steps ST21 to ST28) of forming the second element 200 will be described below by using FIG. 6.

As shown in FIG. 6, the intermediate layer 212 is formed at the second principal surface 213b of the piezoelectric layer 213 (step ST21). The intermediate layer 212 is formed into a film by, for example, a sputtering method by using a material such as silicon oxide. A surface of the intermediate layer 212 on the opposite side from the piezoelectric layer 213 may be subjected to the planarization process by, for example, CMP as appropriate.

Next, the support substrate 211 is bonded to the second principal surface 213b of the piezoelectric layer 213. Thus, the support substrate 211 and the piezoelectric layer 213 are attached to each other (step ST22). The support substrate 211 is bonded to the piezoelectric layer 213 by, for example, direct bonding, plasma-activated bonding, atomic diffusion bonding, or the like.

Next, the piezoelectric layer 213 is formed into a thin plate by, for example, subjecting the piezoelectric layer 213 to grinding and polishing (step ST23). The piezoelectric layer 213 is subjected to polishing by mechanical polishing or CMP, for example. In this way, the piezoelectric layer 213 is formed with a thickness equal to or below about 1 μm, for example. The method of forming the piezoelectric layer 213 into the thin film in step ST23 is not limited to polishing. For example, a damage layer may be formed inside the piezoelectric layer 213 by ion implantation, and the piezoelectric layer 213 may be formed into a thin film by peeling a layer located on a first principal surface of the formed damage layer.

Next, the second functional electrode 230 is formed at the first principal surface 213a of the piezoelectric layer 213 (step ST24). The second functional electrode 230 is formed by a deposition lift-off method, for example. That is to say, in step ST24, a resist is formed into a pattern on the first principal surface 213a of the piezoelectric layer 213 by, for example, photolithography, and a metal is vapor-deposited thereon. Thereafter, the resist is removed and a metal film located at a position where the resist is not removed is formed as the second functional electrode 230.

Next, the through electrodes 241 are formed to extend through the substrate 210 (step ST29). In the first example embodiment, multiple pores are formed from the principal surface of the substrate 210 on the opposite side from the piezoelectric layer 213 to extend through toward the second functional electrode 230 in the Z direction, and the through electrodes 241 are formed by filling the formed pores by plating. In the first example embodiment, the pores for providing the through electrodes 241 are formed by DRIE, for example.

Next, a sacrificial layer 311S is formed at the first principal surface 213a of the piezoelectric layer 213 (step ST25). The sacrificial layer 311S is provided at a region to form the void 311 inside the shield 310. In other words, the sacrificial layer 311S is provided to partially cover the second functional electrode 230. The sacrificial layer 311S is formed into a film by, for example, sputtering while using a material such as zinc oxide (ZnO).

Next, the shield 310 is formed to cover the sacrificial layer 311S (step ST26). The shield 310 is formed by a deposition lift-off method, for example. That is to say, in step ST26, a resist is formed into a pattern on the first principal surface 213a of the piezoelectric layer 213 by, for example, photolithography, and a metal is vapor-deposited thereon. Thereafter, the resist is removed and a metal film located at a position where the resist is not removed is formed as the shield 310. Here, an adhesion layer made of, for example, Ti, NiCr, or the like may be provided between layers of the shield 310 and the sacrificial layer 311S.

Next, the sacrificial layer 311S is removed and the void 311 is formed inside the shield 310 (step ST27). The sacrificial layer 311S is removed by wet etching. In this case, an etchant for dissolving the sacrificial layer 311S is poured in from a space between an end portion in the Y direction of the shield 310 and the first principal surface 213a of the piezoelectric layer 213.

Then, the second portion 322 and the bonding portion 323 of the seal 320 are formed at the first principal surface 213a of the piezoelectric layer 213 (step ST28). The second portion 322 and the bonding portion 323 of the seal 320 are formed by, for example, a deposition lift-off method. That is to say, in step ST28, a resist is formed into a pattern on the first principal surface 213a of the piezoelectric layer 213 by photolithography, and a metal is vapor-deposited thereon. Thereafter, the resist is removed and a metal film located at a position where the resist is not removed is formed as the second portion 322 and the bonding portion 323.

The second element 200 of the present example embodiment can be manufactured by the above-described process. The process shown in FIG. 6 is merely schematically illustrated and can be modified as appropriate. For example, the process (step ST29) of forming the through electrode 241 may be performed after the process (step ST26) of forming the shield 310.

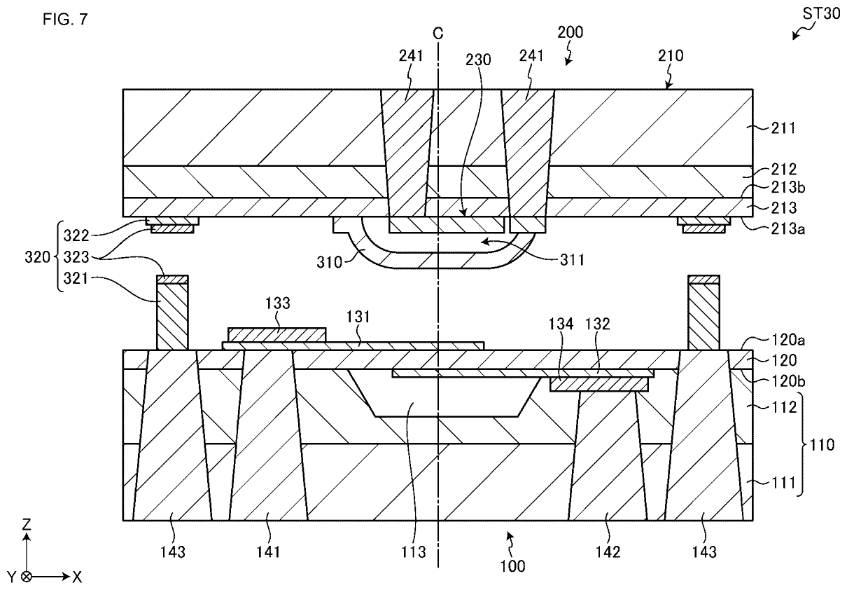

FIG. 7 is a diagram for explaining the process of bonding the first element 100 to the second element 200. After the first element 100 and the second element 200 are manufactured in accordance with the above-described processes, the first element 100 is bonded to the second element 200 as shown in FIG. 7 (step ST30). Bonding of the first element 100 to the second element 200 is performed by metallic bonding, in which the bonding portions 323 are attached to each other by Au—Au bonding, for example. In the first example embodiment, step ST30 is performed in an inert gas atmosphere having a higher pressure than the atmospheric pressure. Thus, the pressure of the void 330 between the first element 100 and the second element 200 can be set higher than the atmospheric pressure. Here, in the case where the seal 320 is defined by an insulator, the first portion and the second portion of a sealing frame 320 are bonded together by plasma-activated bonding, for example.

The piezoelectric device 1 of the present example embodiment can be manufactured in accordance with the above-described processes. The process shown in FIG. 7 is merely schematically illustrated and can be modified as appropriate.

As described above, the example of the method of manufacturing the piezoelectric device according to the first example embodiment includes the process (steps ST11 and ST16) of forming the first functional electrode 130 at least at one of the first principal surface 120a of the piezoelectric layer 120 and the second principal surface 120b, the process (step ST13) of bonding the support 110 to the second principal surface 120b of the piezoelectric layer 120, the process (step ST15) of grinding and thinning a portion of the piezoelectric layer 120 having the thickness in the first direction, the process (step ST26) of providing the shield 310 between the piezoelectric layer 120 and the substrate 210, and the process (step ST30) of providing the substrate 210 having the thickness in the first direction to be opposed to the first principal surface 120a of the piezoelectric layer 120 with the space therebetween in the first direction. The shield 310 is provided at the position at least partially overlapping the first functional electrode 130 in plan view in the first direction. The distance from the center C of the shield 310 to the piezoelectric layer 120 is smaller than the distance from the center C of the shield 310 to the substrate 210. Thus, the operating heat of the first functional electrode 130 is more likely to be conducted to the shield 310, so that the heat dissipation property of the first functional electrode 130 can be improved.

Preferably, the method further includes the process (step ST24) of providing the substrate e 210 with the second functional electrode 230. The shield 310 is provided at the position at least partially overlapping the second functional electrode 230 in plan view in the first direction. Accordingly, it is possible to reduce or prevent the impact of the electromagnetic wave generated by the operation of the first functional electrode 130 on the operation of the second functional electrode 230.

Preferably, the method further includes the process (steps ST19 and ST28) of providing the seal 320 between the piezoelectric layer 120 and the substrate 210. In the process (steps ST19 and ST28) of providing the seal 320, the seal 320 is provided to surround the first functional electrode 130 in plan view in the first direction. In the process (step ST30) of providing the substrate 210, the substrate 210 is bonded to the piezoelectric layer 120 through the seal 320 such that the void surrounded by the piezoelectric layer 120, the substrate 210, and the seal 320 is airtight. The process (step ST30) of providing the substrate 210 is performed in the atmosphere having a higher pressure than the atmospheric pressure. In this way, the pressure inside the void 330 can be set higher than the atmospheric pressure and the heat dissipation attributed to the convection is provided, so that the heat dissipation property can be further improved.

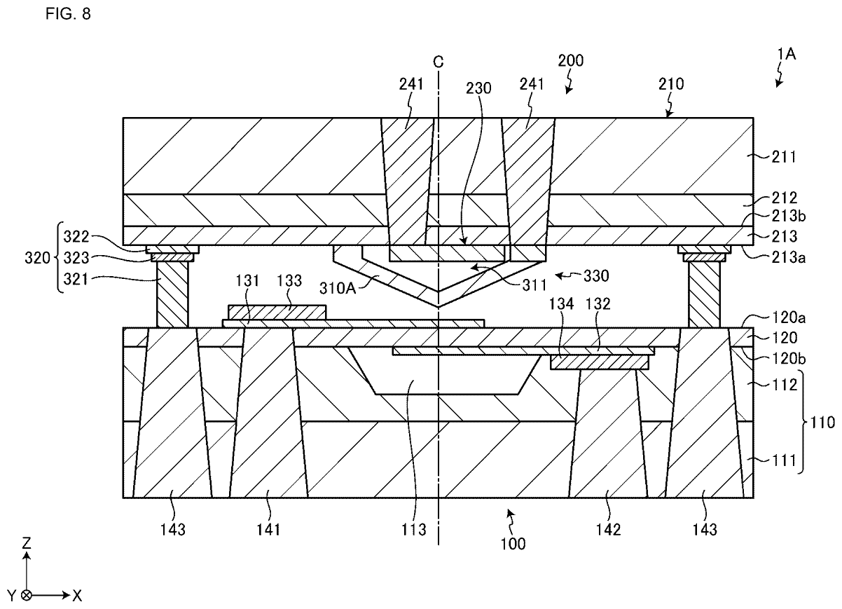

FIG. 8 is a schematic sectional view showing an example of a piezoelectric device according to a second example embodiment of the present invention. As shown in FIG. 8, a piezoelectric device 1A according to the second example embodiment is different from the first example embodiment in that a distance from a shield 310A to the piezoelectric layer 120 at the center C of the shield 310A is different from the distance at a position other than the center C of the shield 310A.

As shown in FIG. 8, in the second example embodiment, the distance from the center of the shield 310A to the piezoelectric layer 120 is smaller than the distance from the position other than the center C of the shield 310A to the piezoelectric layer 120. That is, at the center C of the shield 310A, the distance to the first principal surface 120a of the piezoelectric layer 120 is the smallest. In this manner, the heat dissipation property of the first functional electrode 130 can be further improved.

As described above, in the piezoelectric device according to the second example embodiment, the distance from the shield 310A to the piezoelectric layer 120 at the center C of the shield 310A is different from the distance at a position other than the center C of the shield 310A. The distance from the center of the shield 310A to the piezoelectric layer 120 is smaller than the distance from the position other than the center C of the shield 310A to the piezoelectric layer 120. This makes it possible to improve the heat dissipation property at the geometric center of the excitation region of the first functional electrode 130 where a lot of the operating heat is generated.

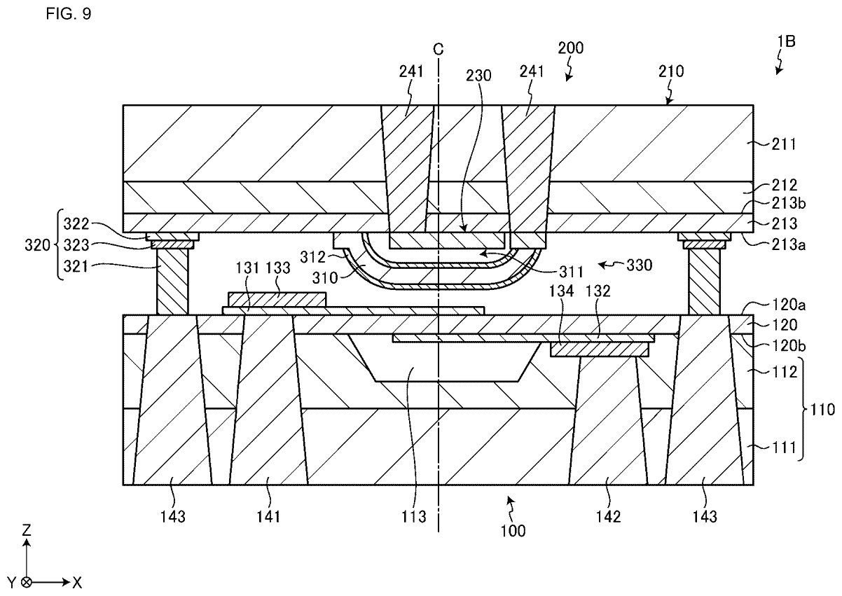

FIG. 9 is a schematic sectional view showing an example of a piezoelectric device according to a third example embodiment of the present invention. As shown in FIG. 9, a piezoelectric device 1B according to the third example embodiment is different from the first example embodiment in that a covering layer 312 is provided at a surface of the shield 310.

The covering layer 312 covers the shield 310. In the example of FIG. 9, the covering layer 312 covers both sides in the Z direction of the shield 310. The covering layer 312 is made of a material having lower electric conductivity than that of the shield 310 and having at least one of thermal conductivity and emissivity (a radiation factor) higher than that of the shield 310. Here, the material of the covering layer 312 need not be a material that shields electromagnetic waves. In the third example embodiment, since the shield 310 is made of a metal such as, for example, Al, Cu, Au, and Ag, the covering layer 312 is made of, for example, a carbon material such as graphene, iron (Fe), or the like. Thus, the heat dissipation property of the first functional electrode 130 can be improved.

As described above, the piezoelectric device 1B according to the third example embodiment further includes the covering layer 312 provided at the surface of the shield 310. The covering layer 312 has a lower electric conductivity than that of the shield 310 and a higher thermal conductivity than that of the shield 310. In this way, the heat dissipation property of the first functional electrode 130 can be further improved.

Meanwhile, the piezoelectric device 1B according to the third example embodiment further includes the covering layer 312 provided at the surface of the shield 310. The covering layer 312 has a lower electric conductivity than that of the shield 310 and a higher emissivity (the higher radiation factor) than that of the shield 310. In this way, the heat dissipation property of the first functional electrode 130 can be further improved.

The above-described example embodiments are intended to facilitate understanding of the present invention and are not intended to restrict or limit the interpretation of the present invention. The present invention can be modified/improved without departing from the scope thereof, and the present invention also includes equivalents thereto.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a piezoelectric layer having a thickness in a first direction and including a first principal surface and a second principal surface on an opposite side from the first principal surface;
a support on a second principal surface side of the piezoelectric layer;
a first functional electrode on at least one of the first principal surface and the second principal surface of the piezoelectric layer;
a substrate opposed to the first principal surface of the piezoelectric layer with a space therebetween in the first direction, including a second functional electrode, and having a thickness in the first direction; and
a shield between the piezoelectric layer and the substrate; wherein
the shield is located at a position at least partially overlapping the first functional electrode in plan view in the first direction; and
a distance from a center of the shield to the piezoelectric layer is smaller than a distance from the center of the shield to the substrate.

2. The piezoelectric device according to claim 1, wherein the support includes a void portion at a position at least partially overlapping the first functional electrode in plan view in the first direction.

3. The piezoelectric device according to claim 1, wherein the shield is located at a position at least partially overlapping the second functional electrode in plan view in the first direction.

4. The piezoelectric device according to claim 1, further comprising:
a seal between the piezoelectric layer and the substrate; wherein
the first functional electrode is located in a region surrounded by the seal in plan view in the first direction;
a void surrounded by the piezoelectric layer, the substrate, and the seal is airtight; and
a pressure inside the void is higher than an atmospheric pressure.

5. The piezoelectric device according to claim 1, wherein
a distance from the shield to the first principal surface of the piezoelectric layer at the center of the shield is different from a distance from the shield to the first principal surface of the piezoelectric layer at a position other than the center of the shield; and
the distance from the center of the shield to the piezoelectric layer is smaller than the distance from the position other than the center of the shield to the piezoelectric layer.

6. The piezoelectric device according to claim 1, further comprising:
a covering layer on a surface of the shield; wherein
the covering layer has a lower electric conductivity than an electric conductivity of the shield and a higher thermal conductivity than a thermal conductivity of the shield.

7. The piezoelectric device according to claim 1, further comprising:
a covering layer on a surface of the shield; wherein
the covering layer has a lower electric conductivity than an electric conductivity of the shield and a higher emissivity than an emissivity of the shield.

8. The piezoelectric device according to claim 1, wherein the piezoelectric layer includes lithium niobate, lithium tantalate, or crystal.

9. The piezoelectric device according to claim 1, wherein the first functional electrode includes an upper electrode on the first principal surface and a lower surface on the second principal surface.

10. The piezoelectric device according to claim 9, wherein
the upper electrode includes an upper circular main electrode portion and an upper extending portion extending from the upper circular main electrode; and
the lower electrode includes a lower circular main electrode portion and a lower extending portion extending from the lower circular main electrode.

11. The piezoelectric device according to claim 9, wherein each of the upper and lower electrodes includes aluminum, platinum, copper, tungsten, or molybdenum, or an alloy including at least one of aluminum, platinum, copper, tungsten, or molybdenum.

12. The piezoelectric device according to claim 9, wherein each of the upper and lower electrodes includes an adhesive layer including titanium or a nickel-chromium alloy.

13. The piezoelectric device according to claim 1, wherein the support includes a support substrate and an intermediate layer between the support substrate and the piezoelectric layer.

14. The piezoelectric device according to claim 13, wherein the support substrate includes silicon or crystal.

15. The piezoelectric device according to claim 13, wherein the intermediate layer includes silicon oxide.

16. The piezoelectric device according to claim 1, further comprising:
a second piezoelectric layer on the substrate; wherein
the second functional electrode is provided on a surface of the second piezoelectric layer facing the piezoelectric layer; wherein
the shield is located between the piezoelectric layer and the second piezoelectric layer.

17. The piezoelectric device according to claim 1, wherein the shield includes aluminum, copper, gold, or silver.

18. The piezoelectric device according to claim 1, wherein the shield is electrically connected to ground.

19. The piezoelectric device according to claim 1, wherein the shield has an arch shape.

20. The piezoelectric device according to claim 4, wherein
the seal includes a first portion, a second portion, and a bonding portion between the first and second portions;
the first and second portions include aluminum; and
the bonding portion includes gold.
